(19) United States
(12) Patent Application Publication
(10) Pub. No.: US 2026/0066873 A1
(43) Pub. Date: Mar. 5, 2026

(54) BULK ACOUSTIC WAVE FILTER

(71) Applicant: STMICROELECTRONICS INTERNATIONAL N.V., Geneva (CH)

(72) Inventor: Patrick POVEDA, Monthodon (FR)

(21) Appl. No.: 19/305,036

(22) Filed: Aug. 20, 2025

(30) Foreign Application Priority Data
Aug. 27, 2024 (FR) 2409152

(51) Int. Cl. H03H 9/54; H03H 9/02; H03H 9/13; H03H 9/205; H03H 9/56

(52) U.S. Cl. CPC H03H 9/547; H03H 9/02157; H03H 9/131; H03H 9/205; H03H 9/564

(57) ABSTRACT

The present disclosure relates to a method for manufacturing a bulk acoustic wave filter. An example of this method includes transferring a first structure onto a second structure. The first structure includes, on a top face of a first substrate, a piezoelectric material layer overlaid by a first electrode. The second structure includes, on a top face of a second substrate, an insulating layer. The insulating layer includes a cavity formed from the top face of the insulating layer. In transferring the first structure, via its top face, onto the top face of the second structure, the first electrode is aligned with the cavity within the insulating layer.

### CROSS REFERENCE TO RELATED APPLICATION(S)

This application claims the priority benefit of French Patent Application Number 2409152, filed on Aug. 27, 2024, entitled “Filtre à ondes acoustiques de volume” which is hereby incorporated by reference to the maximum extent allowable by law.

### TECHNICAL FIELD

The present disclosure relates generally to electronic devices, and more particularly Bulk Acoustic Wave or BAW filters.

### BACKGROUND

Numerous electronic devices comprise at least one bulk acoustic wave filter. For example, such filters are integrated in mobile phones, or smartphones, to avoid the operation of a radiofrequency communications receive channel of the telephone to be disturbed by interferences caused by radiofrequency signals emitted by other electronic devices, or by noise from outer radiofrequency sources.

Two types of bulk acoustic wave filters have already been proposed: the so-called SMR (Solidly Mounted Resonator) filters on one side, and the so-called FBAR (thin-Film Bulk Acoustic Resonator) filters also referred to as “membrane” bulk acoustic wave filters, on the other side. A SMR filter conventionally comprises a membrane made of an insulating material on, and in contact with, a Bragg mirror, and a piezoelectric layer located on the membrane and interposed between bottom and top electrodes. A FBAR filter differs from the SMR filter mainly in that in the case of the FBAR filter, the Bragg mirror is replaced with an air cavity above which the membrane is suspended. Providing the air cavity gives the FBAR filter a better efficiency than that of SMR filter. Indeed, the air cavity provides an acoustic insulation higher than that obtained with a Bragg mirror having several bilayers (around some fifteen bilayers would allow an insulation equivalent to that of an air cavity to be reached, that would be very difficult to implement in practice), resulting in reduced energy losses.

However, existing acoustic wave filters, particularly existing FBAR filters, suffer from various drawbacks. FBAR filters are especially complicated and costly to implement, as the current manufacturing methods of such filters need an accurate control of the flatness of the structure, and implement a difficult step of forming the air cavity by removing a sacrificial layer. Furthermore, FBAR filters suffer from overheating and mechanical strength issues. Hence, it is difficult to miniaturize existing FBAR filters.

There is a need to overcome some or part of the drawbacks of existing bulk acoustic wave filters, notably FBAR filters, and their manufacturing methods. It would particularly be desirable to make the methods for manufacturing such filters easier, and to be able to implement FBAR filters having higher mechanical strength and thermal performance than those of existing FBAR filters. It would allow to miniaturize more easily FBAR filters.

### BRIEF SUMMARY

To this end, one embodiment provides a method for manufacturing a bulk acoustic wave filter, including a step for transferring a first structure onto a second structure, the first structure including, on a top face of a first substrate, a piezoelectric material layer overlaid by a first electrode,
the second structure including, on a top face of a second substrate, an insulating layer, the insulating layer including a cavity formed from the top face of the insulating layer, the transfer step consisting in transferring the first structure, via its top face, onto the top face of the second structure, the first electrode being aligned with the cavity within the insulating layer.

According to an embodiment, during the transfer step, the first structure includes, on the top face of the first electrode, another insulating layer, the insulating layer of the second structure being brought into contact with the other insulating layer of the first structure.

According to an embodiment, at the end of the transfer step, the first electrode of the first structure does not contact with the bottom and side flanks of the cavity.

According to an embodiment, the method includes, after the transfer step, a step for forming a second electrode on the face of the piezoelectric layer opposite the cavity, the second electrode being formed at least in part in line with the first electrode.

According to an embodiment, the method includes, after the transfer step, a step for forming an opening, through the piezoelectric layer, in line with the first electrode.

According to an embodiment, the method includes, after the step for forming the opening through the piezoelectric layer, a step for forming a conductive via within the opening, the conductive via being formed in contact with the first electrode.

Another embodiment provides a bulk acoustic wave filter including:
a substrate;
an insulating layer, formed on a top face of the substrate, and including a cavity, the whole top face of which flush with the top face of the insulating layer;
a piezoelectric layer on the insulating layer;
a first electrode formed on the bottom face of the piezoelectric layer within the cavity, the piezoelectric layer being not open in line with the cavity.

According to an embodiment, the cavity is an air or vacuum cavity.

According to an embodiment, the thickness of the first electrode is less than the depth of the cavity.

According to an embodiment, the piezoelectric layer is made of lithium niobate.

According to an embodiment, the filter includes a second electrode formed on the top face of the piezoelectric layer, at least in part in line with the first electrode.

According to an embodiment, the piezoelectric layer and the insulating layer are separated by a further insulating layer.

Another embodiment provides a method for using the filter as described, including applying a radiofrequency signal between the first and second electrodes that tends to resonate the resonator,
the signal being attenuated if the frequency of the signal is different from the resonance frequency of the resonator.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1, FIG. 2, FIG. 3, FIG. 4, FIG. 5, FIG. 6, FIG. 7, FIG. 8, FIG. 9A, FIG. 9B, and FIG. 10 are each a view of a structure obtained at the end of a step of a method for manufacturing a bulk acoustic wave filter according to one embodiment; and

FIG. 11 is a section view of an electronic device including the bulk acoustic wave filter shown in FIG. 10.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 10°.

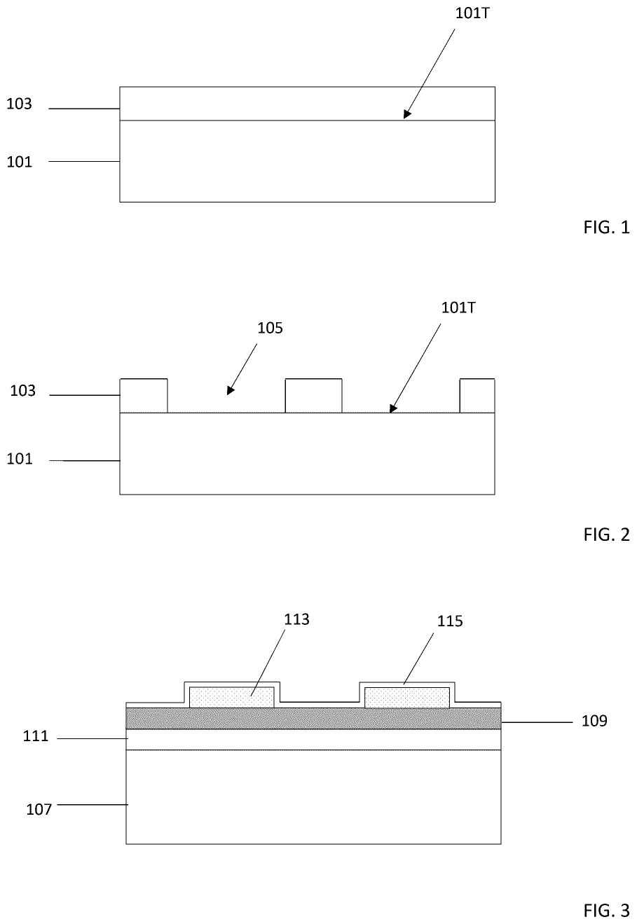

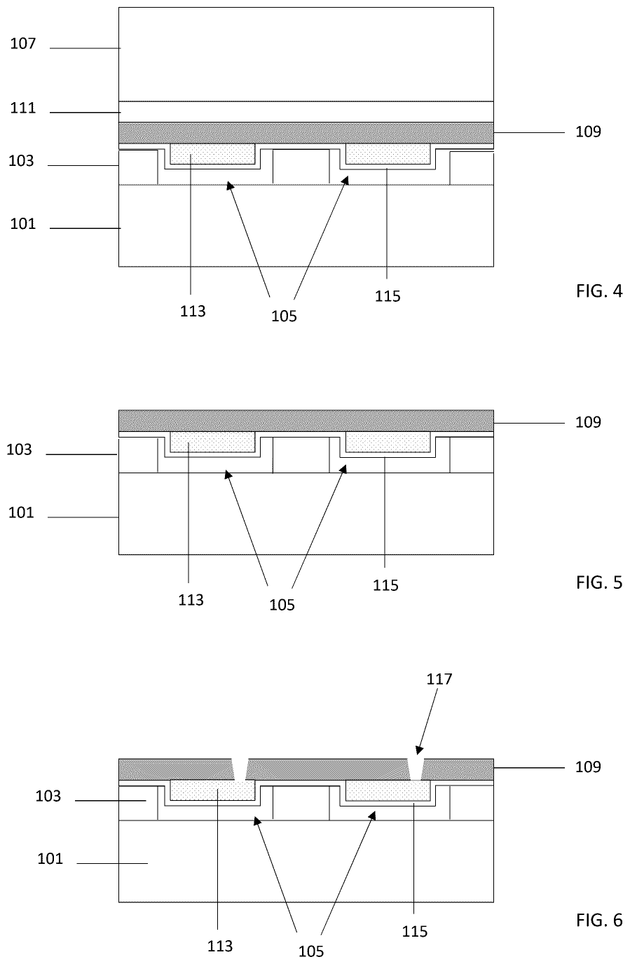

FIG. 1, FIG. 2, FIG. 3, FIG. 4, FIG. 5, FIG. 6, FIG. 7, FIG. 8, FIG. 9A, FIG. 9B, and FIG. 10 are each a view of a structure obtained at the end of a step of a method for manufacturing a bulk acoustic wave filter according to one embodiment.

More precisely, the abovementioned figures illustrate the method for manufacturing an example bulk acoustic wave filter, for example a FBAR-type filter.

FIG. 1 illustrates, with a section view, a starting structure including a semiconductor substrate 101, for example a wafer, or a piece of a wafer, made of a semiconductor material. As an example, the semiconductor substrate 101 is made of silicon. As an example, the substrate 101 is made of a silicon having a high resistivity.

In the example shown, the starting structure further comprises an insulating layer 103 coating a top face 101T of the semiconductor substrate 101. In the example illustrated, the insulating layer 103 is located on, and in contact with, the whole top face 101T of the semiconductor substrate 101. For example, insulating layer 103 has a thickness ranging from 1.2 μm to 2 μm.

Insulating layer 103 is for example made of a mineral material. As an example, insulating layer 103 is made of an oxide or a nitride. Insulating layer 103 is for example made of silicon oxide and/or silicon nitride.

FIG. 2 illustrates, with a section view, a structure obtained at the end of a step of forming cavities 105 in the insulating layer 103 of the structure illustrated in FIG. 1.

In the example shown in FIG. 2, two cavities 105 are formed in the insulating layer 103. In practice, one could provide that a larger number of cavities 105 are formed through the insulating layer 103. Cavities 105 are formed for example from the top face of the insulating layer 103 through insulating layer 103.

As an example, as it is illustrated in FIG. 2, cavities 105 are passing through, and open on the top face 101T of semiconductor substrate.

Alternatively, cavities 105 do not pass through, and have a thickness strictly less than the thickness of the insulating layer 103.

Cavities 105 are for example formed by etching, such as reactive ion etching or RIE.

Cavities 105 have for example a depth ranging from 0.3 μm to 2 μm.

In the embodiment shown in FIG. 2, cavities 105 have side walls being substantially straight and vertical. In this embodiment, cavities 105 are substantially rectangular shaped in section view. As an example, cavities 105 are substantially trapezoidal or rectangular shaped in top view. In variant, the cavities 105 can be of any shape in top view.

FIG. 3 illustrates, with a section view, another starting structure. The starting structure illustrated in FIG. 3 includes, for example, a holder 107. As an example, holder 107 is, for example, a wafer or a piece of wafer made of a semiconductor material. As an example, holder 107 is made of silicon.

The starting structure illustrated in FIG. 3 further includes, on holder 17, a piezoelectric layer 109, i.e. a layer made of a piezoelectric material. Piezoelectric layer 109 extends for example over the top face of holder 107, e.g. over the whole top face of holder 107. As an example, piezoelectric layer 109 is made of a single-crystal material. As an example, the piezoelectric layer 109 is made of lithium niobate (LiNbO₃), lithium titanate (LTO), or aluminium nitride (AlN) doped with scandium. As an example, the piezoelectric layer has a thickness ranging from 50 nm to 250 nm, e.g. a thickness around 100 nm.

As an example, piezoelectric layer 109 is attached to the top face of holder 107, via a bonding layer 111, the bonding layer 111 being in contact, via its bottom face, with the top face of holder 107, and, via its top face, with the bottom face of piezoelectric layer 109.

The starting structure illustrated in FIG. 3 further includes on piezoelectric layer 109, more precisely on the top face of piezoelectric layer 109, electrodes 113. Electrodes 113 are for example formed on, and in contact with, piezolelectric layer 109. In the embodiment shown in FIG. 3, two electrodes 113 were illustrated. In practice, one should provide that a larger number of electrodes 113 are formed. As an example, the electrodes 113 are made of a conductive material, for example a metal or a metal alloy. As an example, the electrodes 113 are made of molybdenum, tungsten, aluminium, copper, or a mixture of two or more of these materials.

In the embodiment shown in FIG. 3, the starting structure further comprises an insulating layer 115 coating the side faces and top face of electrodes 113. In this example, the insulating layer 115 further coats parts of the top face of the piezoelectric layer 109 not coated with electrodes 113. In other words, the insulating layer 115 extends laterally out in line with electrodes 113. The insulating layer 115 is for example more precisely located in contact with the side and top faces of the electrodes 113 and with the parts of the top face of the piezoelectric layer 109 not coated with electrodes 113.

The insulating layer 115 is for example made of the same material as the insulating layer 103 shown in FIGS. 1 and 2. As an example, the insulating layer 115 is for example made of a mineral material. As an example, the insulating layer 115 is made of an oxide or a nitride. The insulating layer 115 is for example made of silicon oxide and/or silicon nitride. The insulating layer 115 acts for example as a passivation layer of the top face of electrodes 113. As an example, the insulating layer 115 has a thickness ranging from 50 nm and 250 nm, e.g. a thickness in the order of 150 nm.

FIG. 4 illustrates, with a section view, a structure obtained at the end of a step of transferring the structure illustrated in FIG. 3 onto the structure illustrated in FIG. 2. More particularly, during this step, the structure illustrated in FIG. 3 is transferred, via its top face (in the orientation shown in FIG. 3), onto the top face of the structure illustrated in FIG. 2. Thus, in FIG. 4, the portion of the structure from the structure illustrated in FIG. 3 is illustrated in a reverse way as compared to its orientation shown in FIG. 3.

During this step, the layers 103 and 115 are brought into contact.

During this step, each electrode 113 goes stay inside a cavity 105. Electrodes 113 formed on the structure shown in FIG. 3 and cavities 105 formed on the structure shown in FIG. 2 are ordered the same way in respect to the surface of the holder 107 and substrate 101, so that each electrode 113 carried by the support 107 faces a cavity 105 in the substrate 101.

During this step, the structure illustrated in FIG. 3 is transferred onto the structure illustrated in FIG. 2 by aligning electrodes 113 with the cavities 105. This transfer step is, for example, aided by an alignment control technic.

As an example, electrodes 113 are rectangular shaped in top view. At the end of this step, the side flanks of electrodes 113 are not in contact with the side flanks of cavities 105 lodging them. As an example, electrodes 113 are, in top view, smaller than cavities 105. As an example, electrodes have a width and a length less than the width and length of cavities 105. As an example, electrodes have a width and a length ranging from 10 μm to 100 μm.

At the end of this step, the bottom faces of electrodes 113, in the orientation shown in FIG. 4, are not in contact with the bottom of cavities 105 lodging them. Electrodes 113 have, for example, a thickness less than the depth of cavities 105. As an example, cavities 105 have a depth ranging from 80 nm to 200 nm.

At the end of this step, layer 109 does not include openings opposite cavity 105.

As an example, at the end of this step, cavity 105 is closed. At the end of this step, cavities 105 include only a gas, for example air or the gas present in the equipment in which the transfer step has been performed. In variant, at the end of this step, cavities 105 include vacuum or partial vacuum.

FIG. 5 illustrates, with a section view, a structure obtained at the end of a step of removing the holder 107 and bonding layer 111 from the structure illustrated in FIG. 4.

As an example, this step is performed by chemical mechanical polishing or CMP. As an example, this step is performed by wet etching.

At the end of this step, the top face of the piezoelectric layer 109 is entirely uncovered and exposed.

FIG. 6 illustrates, with a section view, a structure obtained at the end of a step of forming openings 117 through the piezoelectric layer 109 of the structure illustrated in FIG. 5.

More precisely, during this step, the openings 117 are created through the layer 109 from the top face of the layer 109 in the layer 109. Openings 117 are for example passing through, i.e. they open on the top face of electrodes 113. As an example, an opening 117 is created opposite each electrode 113.

FIG. 7 illustrates, with a section view, a structure obtained at the end of a step of forming electrodes 119 and vias 121 in the structure illustrated in FIG. 6.

More particularly, during this step, one comes forming vias 121, on the top face of the layer 109 and in openings 117 created during the step illustrated in FIG. 6. More particularly, during this step, one further comes forming electrodes 119 opposite electrodes 113

Vias 121 allow the contact recovery of electrodes 113 to be made easier. As an example, vias 121 are made of a conductive material, such as a metal or a metal alloy. As an example, vias 121 are made of molybdenum, tungsten, aluminium, copper, or a mixture of two or more of these materials. Vias 121 have for example, in section view, a T-shape comprising a vertical part extending, in openings 117, from the top face of layer 109, through layer 109 up to the top face of electrode 113 and a horizontal part extending laterally on, and in contact with, the top face of the piezoelectric layer 109 in line with, and in the vicinity of, the vertical part of vias 121.

As an example, electrodes 119 are formed in contact with the top face of the piezoelectric layer 109.

As an example, during this step, an electrode 119 is formed opposite each electrode 113, and thus opposite each cavity 105. As an example, an electrode 119 is formed at least partly in line with a cavity 105. As in the example illustrated in FIG. 7, electrode 109 is for example entirely located in line with cavity 105. As an example, each electrode 119 could extend beyond in line with electrode 113 it covers. This extension allows the contact recoveries of both electrodes 113 and 119 to be made easier.

Electrodes 119 and 113 are for example respectively top and bottom electrodes of a FBAR acoustic filter. As an example, electrodes 119 FBAR are made of a conductive material, such as metal or metal alloy. As an example, the electrodes 119 are made of molybdenum, tungsten, aluminium, copper, or a mixture of two or more of these materials. Electrodes 119 are for example made of a same material as electrodes 113.

As an example, electrodes 119 and vias 121 are formed during a single and same step. Electrodes 119 and vias 121 are, for example, formed by depositing a single and same layer in which patterns are for example defined. When electrodes 119 and vias 121 are simultaneously performed, electrodes 119 and vias 121 are made of the same material.

At the end of this step, a part of the piezoelectric layer 109 is located between electrode 113 and electrode 119. At the end of this step, each portion of layer 109, located between electrodes 119 and 113, forms, with these electrodes 119 and 113, a resonator R of an acoustic filter.

FIG. 8 illustrates, with a section view, a structure obtained at the end of a step of forming an insulating layer 123 on the top face of the structure illustrated in FIG. 7.

More particularly, during this step, the layer 123 is formed on the top face of the structure illustrated in FIG. 7.

Insulating layer 123 is then formed on top of, and for example in contact with, the top face and side flanks of electrodes 119. In addition, insulating layer 123 is formed on top of, and for example in contact with, the top face and flanks of vias 121. Further, insulating layer 123 is formed on top of, and for example in contact with, the top face of the uncoated part of layer 109.

As an example, the insulating layer 123 is made of an oxide, for example made of silicon oxide. Insulating layer 123 is for example made of a same material as insulating layer 115. Insulating layer 123 acts for example as passivation layer of the top face of the structure, particularly of electrodes 119.

FIG. 9A and FIG. 9B illustrate a structure obtained at the end of a step of forming openings 125 through layers 123, 109, and 115 of the structure illustrated in FIG. 8, FIG. 9A being a section view of the structure shown in FIG. 9B along to section plane AA, and FIG. 9B being a horizontal section view of the structure shown in FIG. 9A along to section plane BB shown in FIG. 9A. More precisely, FIG. 9B is a horizontal section view along to section plane BB shown in FIG. 9A when viewed in the direction of the top face of the structure.

More particularly, during this step, an opening 125 is associated to each cavity 105. Openings 125 extend, for example, from the top face of the layer 123, through layer 123, layer 109, layer 115, up to the bottom face of layer 115.

As an example, as it was shown in FIG. 9B, openings 125 could be offset. The cavities 105 then comprises an arm extending horizontally into the layer 103, enabling each opening 125 top open in cavity 105. Alternatively, openings are formed opposite cavities 105, i.e. each opening 125 is vertically aligned with a cavity 105. In this example, each opening 125 opens, in the associated cavity 105, at the top face of cavity 105.

Openings 125 allow for example the pressures on either side of resonator R formed by the electrodes 113 and 119 and layer 109 to be balanced.

Openings 125 are for example in option.

FIG. 10 illustrates, with a section view, a bulk acoustic wave filter 126 obtained at the end of a step of forming a membrane 127 on the top face of the structure illustrated in FIGS. 9A and 9B.

More particularly, during this step, one comes forming a membrane 127 over resonators R.

During this step, one for example comes, in a first stage, forming a sacrificial layer, for example a resin, at the surface of the structure illustrated in FIGS. 9A and 9B. The resin layer is for example etched, then cured so as its top face corresponds to the desired pattern for the membrane 127. At the end of these steps, the sacrificial layer made of resin corresponds to a pad formed above resonators R the top face of which is rounded.

During this step, one for example comes, in a second stage, forming membrane 127 on the top face of the sacrificial layer made of resin. The membrane is for example made of an insulating material, for example an oxide.

During this step, one for example comes, in a third stage, forming openings through membrane 127.

Lastly, one comes removing, through the openings formed in the membrane 127, the sacrificial layer made of resin.

The membrane 127 for example allows a cavity above the top face of resonator R to be defined. The membrane 127 allows a free oscillation of resonator R to be provided without the risk of being stressed or entering into contact with a layer of the structure at its top face or at its bottom face.

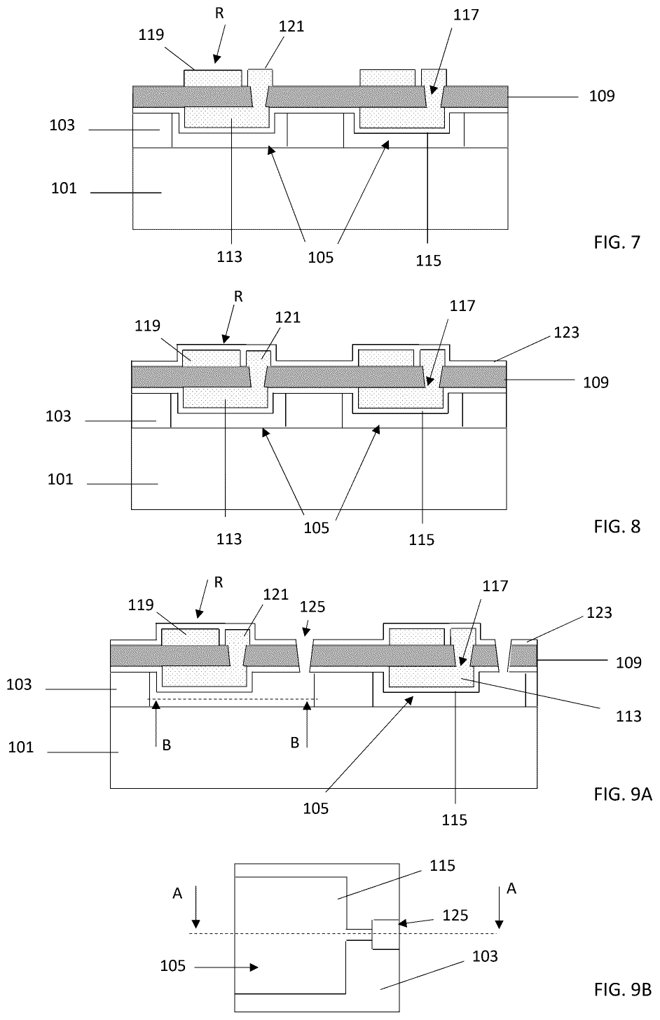

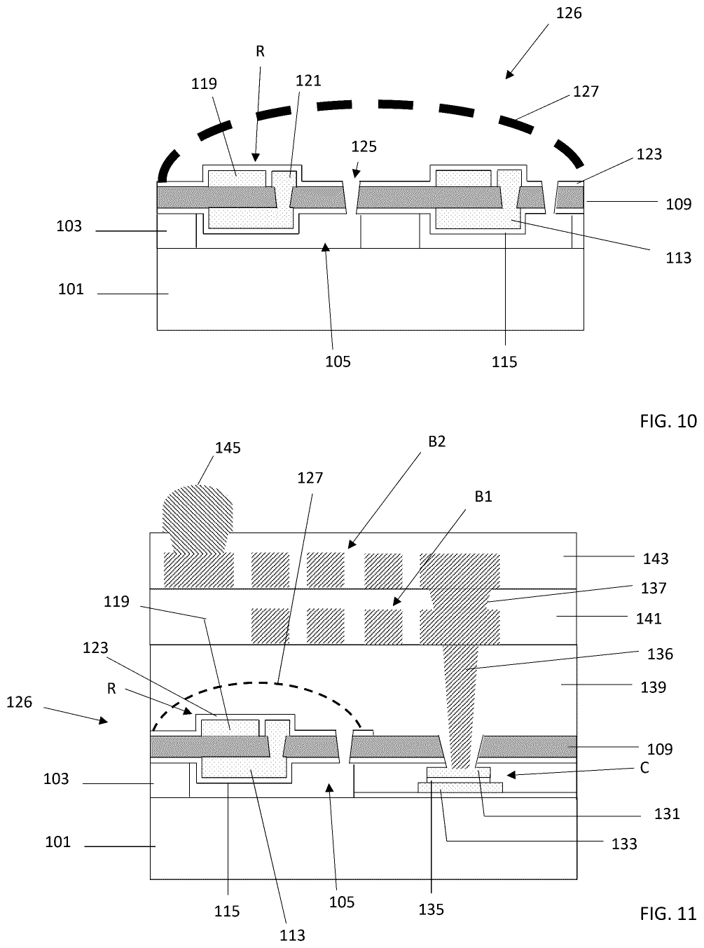

FIG. 11 is a section view of an electronic device including the bulk acoustic wave filter 126 shown in FIG. 10.

As an example, the bulk acoustic wave filter 126 is, within an electronic device, connected to passive elementary electronic component(s). In the example shown in FIG. 11, filter 126 is connected to a capacitor C.

Capacitor C is for example formed in insulating layer 103, and includes two conductive layers, a top one 131 and a bottom another 133 separated by an insulating 135. As an example, the stack of the piezoelectric layer 109 and the insulating layer 115 extends opposite the capacitor C, and is open in line with a part of the capacitor so as to uncover the top face of the top conductive layer 131.

As an example, electrodes of the resonator R are connected to either conductive layers of capacitor C. As an example, the connection between the resonator and the capacitor is performed via conductive tracks, for example formed at the surface of the piezoelectric layer 109, coupling electrodes 113 and 119 to the capacitor.

As an example, the device further includes, at the surface of resonator R and capacitor C, one or more coils B1 and B2. Coils B1 and B2 are for example formed in two different metal levels one above the other. Coils B1 and B2 are for example coupled together and to capacitor C through vias. As an example, coil B1 is coupled to capacitor C through a via 136, and coil B2 is coupled to coil B1 through a via 137.

As an example, coils are formed on an insulating layer 139 coating resonator R and capacitor C. As an example, coils are formed in insulating layers, coil B1 being for example formed in an insulating layer 141, and coil B2 being for example formed in an insulating layer 143. As an example, the insulating layer 139 is formed on, and in contact with, the top face of the membrane 127 and the top face of layer 123 and layer 109. As an example, the insulating layer 141 is formed on, and in contact with, the insulating layer 139. As an example, the layer 143 is formed on, and in contact with, the insulating layer 141.

As an example, coils B1 and B2 are made of a conductive material, such as a metal, i.e. copper. As an example, vias 136 and 137 are made of a conductive material, such as a metal, i.e. copper.

As an example, the device includes a contact recovery for example opposite coil B2. Insulating layer 143 is locally opened so as to uncover a part of the top face of coil B2. As an example, the abovementioned contact recovery is performed via a bump 145 formed in contact with coil B2.

Although it was not illustrated in FIG. 11, so as not to overload the drawing, the bump 145 is for example intended to be coupled or connected to one or more components or circuits outside the device. As an example, bump 145 is intended to be connected to a radiofrequency communications circuit of an electronic device.

In operation, a radiofrequency signal is for example applied, through the bump 145, between electrodes 113 and 119 of filter 126. For example, the radiofrequency signal is an AC voltage. Applying on electrodes 113 and 119 the radiofrequency signal causes for example an alternation of expand and contraction phases of the insulating layer 109. It tends the resonator R of filter 126 to resonate. In the case where the radiofrequency signal has a frequency substantially equal to a resonance frequency of resonator R, the radiofrequency signal is not or slightly attenuated by the filter. In contrast, in the case where the radiofrequency signal has a different frequency from the resonance frequency of resonator R, the radiofrequency signal is strongly attenuated by the filter. For example, it allows avoiding that the operation of a radiofrequency communication receive channel is disturbed by interferences caused by radiofrequency signals emitted by other electronic devices, or by noise from outer radiofrequency sources.

One advantage of the present embodiment is it allows forming cavity 105 without sacrificial layer.

Another advantage of the present embodiment is it allows avoiding a step of removing the sacrificial layer by etching, which forms an especially sensitive step to implement, particularly due to the use of hazardous gas.

Numerous applications might benefit from the advantages provided by the filter, this filter thus being able to be integrated in various types of components.

As an example, filter 126 can be integrated into a component intended to industry. The component can also be used in the field of the Internet of Things or in the field of smart homes. The component can also be used in implementing cloud computing systems, 5G radio frequency communication networks, data centres and servers. The component comprises, for example, wide bandgap materials.

As an example, filter 126 can be integrated into a component intended to be used in personal electronics, for example to increase the volume of information exchanged by radio frequency communication, in 5G communication systems, or more generally in any connected component. The component is, for example, a cell phone, or smartphone, or part of an Internet of Things network. The component is for example connected by 5G, WiFi, or broadband communication. For example, the component comprises high-speed interfaces, for example with advanced filtering and electrostatic discharge protection.

As an example, filter 126 can be integrated into a component intended to be used in communications equipment, or in computers and peripherals. The component is used, for example, in 5G infrastructures and dedicated data centres. The component comprises, for example, silicon carbide diodes, Schottky power transistors, electrostatic discharge protection, and transient voltage suppression diodes. The component can also be used in satellites comprising, for example, integrated passive components for radiofrequency applications.

Various embodiments and variants have been described. Those skilled in the art will understand that certain features of these embodiments can be combined and other variants will readily occur to those skilled in the art.

In particular, although FIGS. 4-10 consider as an example a case where the filter being currently formed comprises two resonators, each located above a cavity 105, those skilled in the art will naturally be able, from the indications of the present disclosure, to adapt this embodiment to any number of resonators located above a same cavity 105 performed into a semiconductor substrate.

From the indications of the present disclosure, those skilled in the art will further be able to perform several filters into the same semiconductor substrate, by providing for example forming several cavities into the same semiconductor substrate, and at least a resonator located in line with each cavity.

Finally, the practical implementation of the embodiments and variants described herein is within the capabilities of those skilled in the art based on the functional description provided hereinabove.

1. A method for manufacturing a bulk acoustic wave filter comprising:
transferring a first structure onto a second structure, the first structure including, on a top face of a first substrate, a piezoelectric material layer overlaid by a first electrode, the second structure including, on a top face of a second substrate, an insulating layer, the insulating layer including a cavity formed from the top face of the insulating layer, and
wherein transferring the first structure comprises transferring the first structure, via its top face, onto the top face of the second structure, the first electrode being aligned with the cavity within the insulating layer.

2. The method according to claim 1, wherein during transferring the first structure onto the second structure, the first structure includes, on the top face of the first electrode, an insulating layer of the first structure, the insulating layer of the second structure being brought into contact with the insulating layer of the first structure.

3. The method according to claim 1, wherein after transferring the first structure onto the second structure, the first electrode of the first structure does not contact a bottom flank and a side flank of the cavity.

4. The method according to claim 1 further comprising, after transferring the first structure onto the second structure, forming a second electrode on a face of the piezoelectric material layer opposite the cavity, the second electrode being formed at least in part in line with the first electrode.

5. The method according to claim 1 further comprising, after transferring the first structure onto the second structure, forming an opening, through the piezoelectric material layer, in line with the first electrode.

6. The method according to claim 5 further comprising, after forming the opening through the piezoelectric material layer, forming a conductive via within the opening, the conductive via being formed in contact with the first electrode.

7. A bulk acoustic wave filter including:
a substrate;
an insulating layer, formed on a top face of the substrate, and including a cavity, the whole top face of which flush with the top face of the insulating layer;
a piezoelectric material layer on the insulating layer;
a first electrode formed on a bottom face of the piezoelectric material layer within the cavity, the piezoelectric material layer being not open in line with the cavity.

8. The bulk acoustic wave filter according to claim 7, wherein the cavity is an air or vacuum cavity.

9. The bulk acoustic wave filter according to claim 7, wherein a thickness of the first electrode is less than a depth of the cavity.

10. The bulk acoustic wave filter according to claim 7, wherein the piezoelectric material layer is made of lithium niobate.

11. The bulk acoustic wave filter according to claim 7 further comprising a second electrode formed on the top face of the piezoelectric material layer, at least in part in line with the first electrode.

12. The bulk acoustic wave filter according to claim 7, wherein the piezoelectric material layer and the insulating layer are separated by a further insulating layer.

13. A method for using the bulk acoustic wave filter according to claim 12 comprising:
applying a radiofrequency signal between the first and second electrodes that may resonate a resonator, and
wherein the signal is attenuated if a frequency of the signal is different from the resonance frequency of the resonator.
